(19) United States
(12) Patent Application Publication
(10) Pub. No.: US 2021/0055610 A1
(43) Pub. Date: Feb. 25, 2021

(54) LIQUID CRYSTAL X-RAY DETECTOR AND MANUFACTURING METHOD FOR THE SAME

(71) Applicant: SESIM. LTD, Uiwang-si (KR)

(72) Inventor: Bong Gyu RHO, Suwon-si (KR)

(73) Assignee: SESIM. LTD, Uiwang-si (KR)

(21) Appl. No.: 17/045,758

(22) PCT Filed: Mar. 18, 2019
(86) PCT No.: PCT/KR2019/003106

§ 371 Date: Oct. 6, 2020

(30) Foreign Application Priority Data
Apr. 20, 2018 (KR) 10-2018-0046212

(51) Int. Cl. G02F 1/1337; H01L 31/115; H01L 31/18

(52) U.S. Cl. CPC G02F 1/133711; H01L 31/18; H01L 31/115

(57) ABSTRACT

Disclosed is a liquid crystal X-ray detector in which only one substrate is used to make a liquid crystal unit by forming one of two alignment films for holding a liquid crystal layer therebetween on a selenium layer. Further disclosed is a method of manufacturing the same. The liquid crystal X-ray detector includes a photoconductor unit and a liquid crystal unit provided on the photoconductor unit. The photoconductor unit includes a first substrate, a selenium layer formed on the first substrate, and a first alignment film formed on the selenium layer. The first alignment film is formed of parylene deposited at a temperature lower than 45° C. in a vacuum atmosphere. The liquid crystal unit includes a second substrate, a second alignment film formed on the second substrate and opposed to the first alignment film, and a liquid crystal layer provided between the first alignment film and the second alignment film.

### BACKGROUND OF THE INVENTION

### 1. Field of the Invention

The present invention relates to an X-ray imaging apparatus. More particularly, the present invention relates to a liquid crystal X-ray detector capable of obtaining an X-ray image of a subject using liquid crystals that change in polarization transmission characteristics with respect to a read beam when being irradiated with X-rays, and a method of manufacturing the same.

### 2. Description of the Related Art

An X-ray imaging apparatus converts a distribution of charges in a layer irradiated with X-rays transmitted through a subject into a digital signal, thereby imaging the interior structure of the subject. The X-ray imaging apparatus is extensively used in medical applications for patient diagnosis, non-destructive building inspection, and the like.

In recent years, X-ray detectors have employed digital technology or liquid crystal cells for improvement in performance thereof. For example, there is an X-ray detector using liquid crystal cells. This X-ray detector is referred to as a liquid crystal X-ray detector or an X-ray sensing liquid crystal detector. The liquid crystal X-ray detector is largely composed of a photoconductive element, a liquid crystal element, a light source, and a photodetector.

When manufacturing a conventional liquid crystal X-ray detector, a photoconductive layer is formed of selenium at a relatively low temperature of about 60° C. and then a method of manufacturing liquid crystal elements, including formation of alignment films and injection of liquid crystals, is performed at a temperature higher than the temperature at which the photoconductive layer is formed. Due to the high temperature of the liquid crystal element manufacturing process, selenium is changed from amorphous to crystalline, resulting in an increase in surface roughness of the photoconductive layer. Therefore, the resolution and precision of an X-ray image of a subject is deteriorated. That is, the reliability of the liquid crystal X-ray detector is deteriorated.

In order to solve this problem, there is an attempt of eliminating an organic alignment film requiring high temperature firing from a selenium photoconductive layer. That is, a technique of forming liquid crystal cells, thinly polishing a glass substrate, and forming a selenium coating on the polished glass substrate is disclosed (see Korean Patent Application Publication No. 10-2008-0069079).

FIG. 5 is a cross-sectional view of a liquid crystal X-ray detector using a polished glass substrate 2a according to Korean Patent Application Publication No. 10-2008-0069079. Referring to FIG. 5, a liquid crystal unit 2 uses a substrate composed of a top substrate 2a and a bottom substrate 2f. An upper alignment film 2b is formed on the top substrate 2a, and a transparent conductive film 2e and a lower alignment film 2d are formed on the bottom substrate. Liquid crystal is injected between the upper alignment film 2b and the lower alignment film 2d to form a liquid crystal layer 2c.

A glass substrate (i.e., top substrate 2a) adjacent to the selenium photoconductive layer 1a is polished to a thickness of about 50 μm, and then an amorphous selenium layer 1a, an insulating film 1b, and a transparent electrode 1c are formed on the polished glass substrate.

However, this conventional method of manufacturing a liquid crystal X-ray detector has problems in that many defects occur during the polishing of the glass substrate 2a, it is difficult to manufacture a large area liquid crystal X-ray detector, and the resolution is deteriorated due to broadening of an electric field in the glass substrate 2a.

### DOCUMENTS OF RELATED ART

### Patent Document

Patent Document 1: Korean Patent Application Publication No. 10-2008-0069079 (published Jul. 25, 2008)

### SUMMARY OF THE INVENTION

An objective of the present invention is to provide a liquid crystal X-ray detector in which only one substrate is used to make a liquid crystal element by forming one of two alignment films for holding a liquid crystal layer therebetween on a selenium layer, the X-ray detector being capable of preventing deformation of or damage to the selenium layer by forming the alignment film formed on the selenium layer at room temperature. Another objective of the present invention is to provide a method of manufacturing the same X-ray detector.

According to one embodiment of the present invention, a liquid crystal X-ray detector includes a photoconductor unit and a liquid crystal unit provided on the photoconductor unit.

The photoconductor unit may include a first substrate, a selenium layer formed on the first substrate, and a first alignment film formed on the selenium layer.

The first alignment film is formed of Parylene deposited at a temperature lower than 45° C. in a vacuum atmosphere.

The liquid crystal unit includes a second substrate, a second alignment film formed on the second substrate and opposed to the first alignment film, and a liquid crystal layer provided between the first alignment film and the second alignment film.

According to one embodiment of the present invention, a method of manufacturing a liquid crystal X-ray detector includes preparing a photoconductor unit, preparing a liquid crystal unit, and bonding the photoconductor unit and the liquid crystal unit to each other.

The preparing of the photoconductor unit may include a first step of forming a selenium layer on the first substrate and a second step of forming a first alignment film on the selenium layer.

The second step may include a coating step of coating a surface of the selenium layer with parylene to form the first alignment film.

Preferably, the second step may further include a vaporization step of vaporizing parylene dimer and a decomposition step of decomposing the vaporized parylene dimer into parylene monomer by applying heat or plasma energy to the vaporized parylene dimer. In this case, the coating step may be performed by depositing the parylene monomer on a selenium layer at a temperature lower than 45° C. in a vacuum atmosphere.

The liquid crystal X-ray detector and the manufacturing method thereof form one of two alignment films required to hold a liquid crystal layer therebetween on a selenium layer. Therefore, it is possible to form a liquid crystal unit using only one glass substrate. In this case, since the alignment film on the selenium layer can be formed at room temperature, it is possible to prevent deformation of and damage to the selenium layer attributable to a high process temperature.

Therefore, the liquid crystal X-ray detector according to the present invention has a photoconductive layer having a uniform thickness, thereby generating no distortion signal attributable to the unevenness of the photoconductive layer. In addition, with the liquid crystal X-ray detector, it is possible to obtain an X-ray image with high precision and high resolution. That is, the liquid crystal X-ray detector according to the present invention provides improved reliability.

In addition, since the liquid crystal X-ray detector according to the present invention does not use a polished glass substrate that has been used in a conventional liquid crystal X-ray detector, it is possible to prevent problems of deterioration of resolution and polishing-induced faults. In addition, a large area liquid crystal X-ray detector can be implemented.

### BRIEF DESCRIPTION OF THE DRAWINGS

The above and other objectives, features, and other advantages of the present invention will be more clearly understood from the following detailed description taken in conjunction with the accompanying drawings, in which:

FIG. 1 is a cross-sectional view illustrating the construction of a liquid crystal X-ray detector according to one embodiment of the present invention;

FIG. 2 is a flowchart illustrating a method of manufacturing a liquid crystal X-ray detector according to one embodiment of the present invention;

FIG. 3 is a diagram illustrating the overall construction of a liquid crystal X-ray detector according to one embodiment of the present invention;

FIG. 4 is a cross-sectional view illustrating the working principle of a liquid crystal X-ray detector according to one embodiment of the present invention; and

FIG. 5 is a cross-sectional view of a liquid crystal X-ray detector using a polished glass substrate according to Korean Patent Application Publication No. 10-2008-0069079.

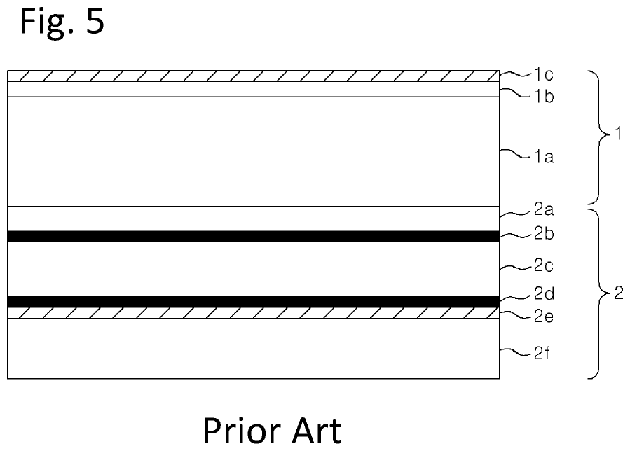

### DESCRIPTION OF THE PREFERRED EMBODIMENTS

The terminology used herein is for the purpose of describing particular embodiments only and is not intended to limit the scope of the present invention. As used herein, the singular forms “a”, “an”, and “the” are intended to include the plural forms as well unless the context clearly indicates otherwise. It will be further understood that the terms “comprises”, “includes”, or “has” when used in this specification specify the presence of stated features, regions, integers, steps, operations, elements and/or components, but do not preclude the presence or addition of one or more other features, regions, integers, steps, operations, elements, components and/or combinations thereof.

In addition, “on” or “above” means on or above an object, and does not necessarily mean an upper position based on the direction of gravity. Also, when a portion of a region, plate, or the like is referred to as being “on another portion or on top of another portion,” it may be directly on, be in contact with, spaced from the other portion, or another portion may be interposed between them.

It is also to be understood that when one element is referred to herein as being “connected to” or “coupled to” another element, it may be connected or coupled directly to the other element, or connected or coupled to the other element via a mediating element interposed therebetween, unless specifically stated otherwise.

In addition, terms used in the specification, “first”, “second”, etc., may be used to describe various components, but the components are not to be construed as being limited to the terms. These terms are used only for the purpose of distinguishing a component from another component.

Herein below, preferred embodiments, advantages, and features of the present invention will be described in detail with reference to the accompanying drawings.

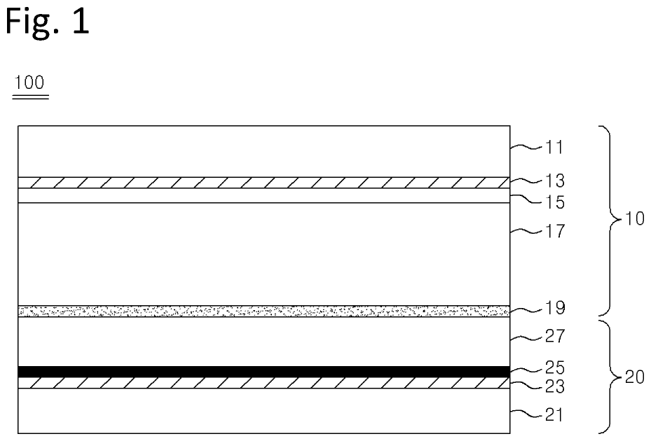

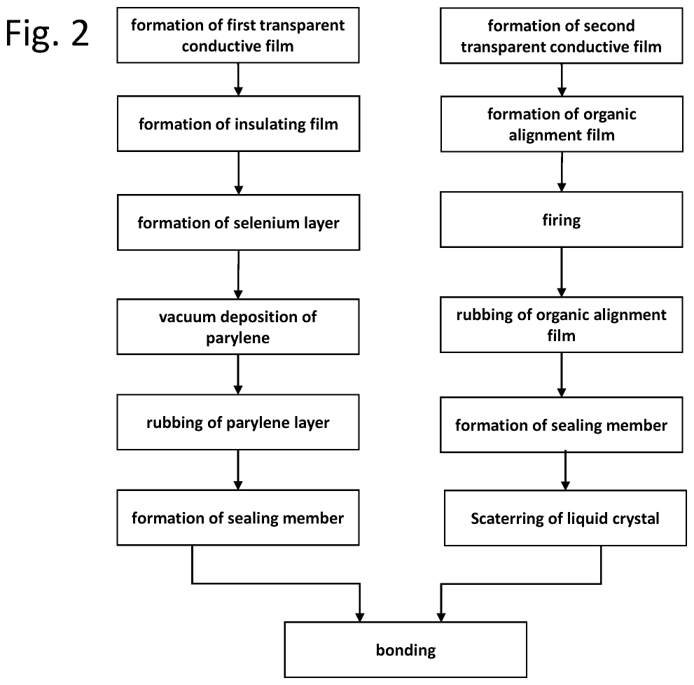

FIG. 1 is a cross-sectional view illustrating the construction of a detection panel of an X-ray detector according to one embodiment of the present invention, and FIG. 2 is a flowchart illustrating a method of manufacturing a liquid crystal X-ray detector according to one embodiment of the present invention. Referring to FIGS. 1 and 2, according to one embodiment of the present invention, a detection panel 100 of a liquid crystal X-ray detector is a combination of a photoconductor unit 10 and a liquid crystal unit 20.

The photoconductor unit 10 of the liquid crystal X-ray detector is configured such that a distribution of electrons and holes changes therein when it is irradiated with X-rays or applied with an electric field. Specifically, the photoconductor unit 10 includes a substrate 11, a transparent conductive film 13, an insulating film 15, a photoconductive layer 17, and an alignment film 19.

The substrate 11 (hereinafter, referred to as first substrate 11) of the photoconductor unit 10 is a base member on which the transparent conductive film 13, the insulating film 15, the photoconductive layer 17, and the alignment film 19 are to be sequentially formed. The substrate 10 is made of transparent glass or resin.

For example, as the polymer material, polyethylene terephthalate (PET), polyethylene sulfone (PES), polyethylene naphthalate (PEN), polyimide (PI), polycarbonate (PC), polymethylmethacrylate (PMMA), ethylenevinylacetate (EVA), amorphous polyethyleneterephthalate (APET), polypropyleneterephthalate (PPT), polyethyleneterephthalate glycerol (PETG), polyarylate (PAR), cycloolefin polymer (COP), polycyclohexylenedimethyleneterephthalate (PCTG), denatured triacetylcellulose (TAC), cycloolefin copolymer (COC), dicyclopentadiene polymer (DCPD), cyclopentadiene polymer (CPD), polyetherimide (PEI), and polydimethylsiloxane (PDMS) are used solely or in combination.

The transparent conductive film 13 (hereinafter referred to as “first transparent conductive film 13”) of the photoconductor unit 10 is an element to which a voltage is applied. The transparent conductive film 13 is formed on one surface of the first substrate 11 and is electrically connected to the driver unit 70 described below.

When a voltage is applied between the transparent conductive film of the photoconductor unit 10 and the transparent conductive film of the liquid crystal unit 20 by the driver unit 70 described below, a DC electric field is created. The electric field causes movement of electrons and holes in the photoconductive layer 17. That is, a distribution of electrons and holes changes in the photoconductive layer 17.

According to the preferred embodiment, the first transparent conductive film 13 is made of a metal oxide or a metal oxide-metal-metal oxide selected from the group consisting of indium tin oxide (ITO), indium zinc oxide (IZO), indium zinc tin oxide (IZTO), aluminum zinc oxide (AZO), gallium zinc oxide (GZO), florin tin oxide (FTO), indium tin oxide-silver-indium tin oxide (ITO-Ag-ITO), indium zinc oxide-silver-indium zinc oxide (IZO-Ag-IZO), indium zinc oxide-silver-indium zinc oxide (IZTO-Ag-IZTO), and aluminum zinc oxide-silver-aluminum zinc oxide (AZO-Ag-AZO).

The first transparent conductive film 13 is made of an organic conductor material such as poly(3,4-ethylenedioxythiophene):poly(styrenesulfonate) (PEDOT:PSS) or polyaniline (PANI). Alternatively, the first transparent conductive film 13 may be made of a metal thin film (for example, a silver thin film or a gold thin film), a film-coated nanowire prepared by coating a silver nanowire, gold nanowire, copper nanowire, or platinum nanowire with a metal thin film, or a carbon based material such as carbon nanotubes or graphene.

Further alternatively, those materials may be used in combination to form the first transparent conductive film 1.

The insulating film 15 of the photoconductor unit 10 is interposed between the first transparent conductive film 13 and the photoconductive layer 17 (i.e., selenium layer 17) to prevent charge transfer between the first transparent conductive film 13 and the photoconductive layer 17.

The insulating film 15 is made of an insulating inorganic material such as silicon dioxide (SiO₂) or an insulating resin such as polycarbonate. The insulating film 15 is formed in the form of a thin film on one surface of the first transparent conductive film 13.

The photoconductive layer 17 of the photoconductor unit 10 is an element for creating charges. When the photoconductive layer 17 is irradiated with X-rays, a large number of electron-hole pairs are generated in the photoconductive layer 17. When this photoconductor layer 17 is exposed to an electric field, the electric field causes movement of electrons and holes. That is, a change in the distribution of charges occurs.

The photoconductive layer 17 is formed in the form of a thin film on the insulating film 15 and is made of selenium.

Preferably, the photoconductive layer 17 is made of amorphous selenium (a-Se). The amorphous selenium (a-Se) is formed through vacuum deposition or coating at low temperatures. Hereinafter, the photoconductive layer 17 made of selenium (especially amorphous selenium) is referred to as “selenium layer 17”.

The most vulnerable one of the physical properties of selenium is the low glass transition temperature Tg. In particular, amorphous selenium has a very low glass transition temperature Tg of 45° C. The selenium layer 17 experiences changes in selenium structure, bandgap, and permittivity, or occurrence of a surface roughness at the glass transition temperature.

Therefore, when the photoconductive layer 17 is made of amorphous selenium, the process temperature needs to be below 45° C. which is the glass transition temperature Tg of amorphous selenium. This will be described below in more detail. The liquid crystal X-ray detector has a pair of alignment films for aligning the orientation of liquid crystals. Of the two alignment films, especially, the alignment film formed on the selenium layer 17 needs to be formed at a temperature below the glass transition temperature Tg of amorphous selenium.

That is, the process of forming the alignment film 19 on the selenium layer 17 needs to be performed at a temperature below 45° C. and preferably needs to be performed at 40° C. that is 5° C. lower than the glass transition temperature Tg of amorphous selenium.

For this reason, in the case of a conventional liquid crystal X-ray detector, the alignment film on the selenium layer 17 is formed by depositing an inorganic material such as SiO₂ in vacuum at a temperature under 40° C. and then rubbing the resulting inorganic layer. However, when the rubbed SiOₓ-based inorganic layer is used as the alignment film, the alignment film is low in anchoring energy and order parameter. Therefore, there is a problem in that the reliability of the liquid crystal is deteriorated.

In order to solve the problem of the SiOₓ-based inorganic alignment film, a low-temperature alignment technique using polyimide is proposed. The low-temperature alignment technique is used to avoid a high temperature firing process for an alignment film. In the technique, the alignment film is formed through the processes of converting polyamide into polyimide, diluting the polyimide with a solvent that is volatilized at a low temperature, wet-coating the diluted polyimide, and firing the polyimide coating for over one week in a vacuum furnace.

However, the low-temperature alignment film has a problem in that the solvent contained in the wet coating is not completely removed but remains. This remaining solvent diffuses into the liquid crystal layer, thereby lowering the specific resistance of the liquid crystal and deteriorating the quality of an X-ray image.

In order to solve the problems of the inorganic alignment film and the low-temperature alignment film, the inventors of the present invention have developed a method of using a rubbed parylene film as an alignment film of a photoconductor unit 10. In the present invention, the alignment film of the photoconductor unit 10 is formed of parylene deposited at a temperature lower than 45° C. in a vacuum atmosphere.

Parylene is organic monomer in powder form. A parylene layer is formed on the selenium layer through vaporization and deposition of parylene. Parylene is changed into polymer and is then deposited on the amorphous selenium at room temperature in vacuum. A parylene film is advantageous in terms that it is highly uniform in thickness, stress-free, highly insulative, and chemically resistant, and has good resistance to humidity.

Hereinafter, an alignment film of a photoconductor unit and a method of forming the alignment film will be described in more detail.

The method of forming the alignment film 19 (hereinafter, referred to as first alignment film 19) of the photoconductor unit 10 includes a vaporization process, a decomposition process, a deposition process, and a rubbing process.

The vaporization process is a process of evaporating parylene dimer powder represented by Formula 1.

This vaporization process may be performed by evaporating the parylene dimer powder at a temperature of 120 to 180° C. (preferably 175° C.) and a pressure of about 1 Torr.

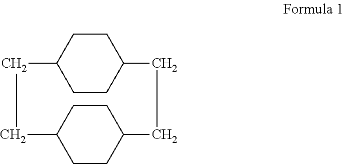 [SMILES: C1CC2CCC1CCC1CCC(CC1)CC2]

The decomposition process is a process of decomposing the evaporated parylene dimer into parylene monomer represented by Formula 2. The decomposition process involves application of thermal energy or plasma energy to the parylene dimer.

Specifically, when thermal energy is used, parylene dimers are decomposed into parylene monomers through pyrolysis at a temperature of 620 to 700° C. under a pressure of about 0.5 Torr. When plasma energy is used, parylene dimers are decomposed into parylene monomers by the plasma energy.

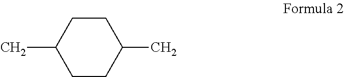

The deposition process is a process of depositing parylene monomers on the selenium layer 17 in a vacuum atmosphere, thereby forming a film of parylene polymer the basic unit of which is represented by Formula 3.

The deposition process is preferably performed at a pressure of about 0.5 Torr and a process temperature below 45° C. which is the glass transition temperature Tg of amorphous selenium, more preferably at a temperature of 40° C. or lower, and most preferably at a temperature of about 25° C.

In the deposition process, the first substrate 11 on which the photoconductor unit 10 composed of the first transparent conductive film 13, the insulating film 15, and the selenium layer 17 is introduced into a vacuum chamber so that polymerization to form a parylene coating can be performed at a low pressure and a room temperature that is 30° C. or lower.

According to one embodiment of the present invention, the vaporization process, the decomposition process, and the deposition process are performed in physically separated vacuum chambers or furnaces, respectively.

When the first alignment film formation method described above is used, the first alignment film 19 can be formed at a room temperature. Therefore, the selenium layer 17 is not affected by the process temperature at which the first alignment film 19 is formed. Therefore, the liquid crystal X-ray detector has the photoconductive layer 17 with a uniform thickness and an even surface. Therefore, the liquid crystal X-ray detector can accurately and precisely detect X-rays transmitted through a subject 90 without distortion signals which may occur due to a non-uniform thickness of the photoconductive layer 17.

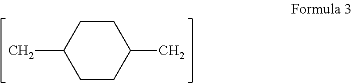

The rubbing process is a process of rubbing the parylene layer 19 formed on the selenium layer 17 and forming a sealing member on the rubbed parylene layer 19. The sealing member is made of thermosetting resin or UV-curable resin. Preferably, the sealing member is made of UV-curable resin to improve productivity.

When the roughening process is completed, the photoconductor unit 10 including the first transparent conductive film 13, the insulating film 15, the selenium layer 17, and the first alignment film 19 that are sequentially stacked on the first substrate 11 is obtained.

The photoconductor unit 10 that is manufactured through the method described above is combined with the liquid crystal unit 20 described below, thereby producing the liquid crystal X-ray detector according to the present invention.

Hereinafter, the liquid crystal unit 20 of the liquid crystal X-ray detector according one embodiment of the present invention will be described.

The liquid crystal unit 20 is bonded to the photoconductor unit 10 and functions to selectively transmit specific polarized wavelengths of a read beam. The liquid crystal unit 20 includes a substrate 21, a transparent conductive film 23, an alignment film 25, and a liquid crystal layer 27.

The substrate 21 (hereinafter, referred to as second substrate 21) of the liquid crystal unit 20 is a base member on which the transparent conductive film 23, the alignment film 25, and the liquid crystal layer 27 are to be formed. The second substrate 21 is made of transparent glass or polymer.

The transparent conductive film 23 (hereinafter referred to as “second transparent conductive film 23”) of the liquid crystal unit 20 is an element to which a voltage is applied. The second transparent conductive film 23 is formed on one surface of the second substrate 21 and is electrically connected to the driver unit 70 described below.

When a voltage is applied between the first transparent conductive film 13 and the second transparent conductive film 23, a DC electric field is generated between the first transparent conductive film 13 and the second transparent conductive films 23, thereby moving electrons and holes in the photoconductive layer 17. That is, a distribution of electrons and holes is changed in the photoconductive layer 17.

According to the preferred embodiment, the second transparent conductive film 23 is made of a metal oxide such as indium tin oxide (ITO) or indium zinc oxide (IZO), or a metal oxide-metal-metal oxide such as indium tin oxide-silver-indium tin oxide (ITO-Ag-ITO).

The second transparent conductive film 23 is made of an organic conductor material such as poly(3,4-ethylenediorythiophene):poly(styrenesulfonate) (PEDOT:PSS) or polyaniline (PANI). Alternatively, the second transparent conductive film 23 may be made of a metal thin film such as a silver thin film or a gold thin film. Further alternatively, it may be made of a metal-coated nanowire or a carbon-based material such as carbon nanotube or graphene.

Further alternatively, those materials may be used in combination to form the second transparent conductive film 23.

When the electric charge distribution in the photoconductor unit 10 changes due to X-ray irradiation and voltage application thereto, the orientation of the liquid crystals in the liquid crystal layer 27 of the liquid crystal unit 20 changes and the polarization transmission characteristic of the liquid crystal layer 27 with respect to the read beam accordingly changes. The liquid crystal layer 27 of the liquid crystal unit 20 includes a plurality of liquid crystal molecules injected into a gap between the first alignment film 19 and the second alignment film 25.

The alignment film 25 (hereinafter referred to as “second alignment film 25”) of the liquid crystal unit 20 is formed on the second transparent conductive film 23. When the liquid crystal unit 20 is bonded to the photoconductor unit 10, the second alignment film 25 is arranged to face the first alignment film 19.

The second alignment film 25 functions to uniformly align the liquid crystal molecules in conjunction with the first alignment film 19.

Unlike the first alignment film 19, the second alignment film 25 can be formed without any constraint of temperature (for example, constraint of a temperature of 45° C. or higher). That is, the second alignment film 25 can be formed using the same process as in a conventional manufacturing method of a liquid crystal panel of a TN, STN, or TFT LCD device.

For example, the second alignment film 25 may be a wet-coated organic alignment film. In this case, the second alignment film 25 is formed by coating a surface of the cleaned second substrate 21 with a polyamide solution prepared by dissolving polyamide in a solvent, and then baking the polyamide coating at a temperature of about 150° C. for about 1 hour. Through this process, the polyamide is converted into polyimide. Thus, the second alignment film 25 made of polyimide can be formed. Here, the process of coating the surface of the second substrate 21 with polyamide may be performed through wet coating such as spin coating or printing.

Meanwhile, when the second alignment film 25 is formed with a polyamide solution to which spacers are added, a spacer scattering process can be omitted. That is, the second alignment film 25 to which spacers are fixed can be obtained by adding a small number of spacers to a polyamide solution which is a liquid crystal aligning agent, coating a substrate with the polyamide solution containing the spacers through spin coating or wet coating, and firing the resulting coating layer formed on the substrate.

After the second alignment film 25 is coated on the substrate, the second alignment film 25 is rubbed, and then a sealing member is formed on the rubbed second alignment film 25. The sealing member is made of a thermosetting resin or a UV-curable resin.

Thereafter, liquid crystals are scattered on the second alignment film 25. Thus, the liquid crystal unit 20 in which the second transparent conductive film 23, the second alignment film 25, and the liquid crystal layer 27 are sequentially formed on the second substrate 21 is obtained.

Next, the liquid crystal unit 20 is bonded to the photoconductor unit 10. Thus, the liquid crystal X-ray detector according to the present invention can be manufactured through a one drop process.

Hereinafter, the overall construction of a liquid crystal X-ray detector according to one embodiment of the present invention and the working principle thereof will be described.

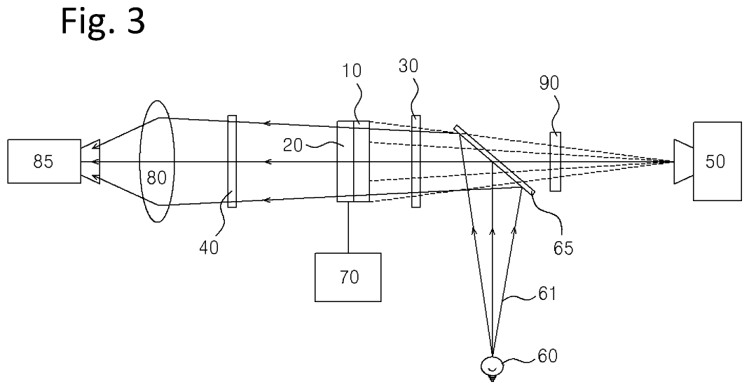

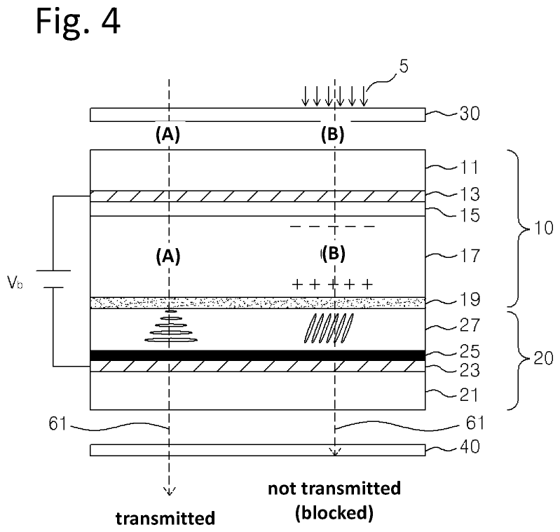

FIG. 3 is a diagram illustrating the overall construction of a liquid crystal X-ray detector according to one embodiment of the present invention, and FIG. 4 is a cross-sectional view illustrating the liquid crystal X-ray detector according to one embodiment of the present invention.

Referring to FIGS. 3 and 4, according to one embodiment of the present invention, a liquid crystal X-ray detector further includes an X-ray output unit 50, a light source 60, a driver unit 70, a half mirror 65, a polarizing plate 30, an analyzer 40, an imaging lens 80, and an image pickup unit 85, in addition to the photoconductor unit 10 and the liquid crystal unit 20.

The X-ray output unit 50 generates X-rays and emits them to the outside.

The light source 60 is an apparatus that emits a read beam 61. The light source 60 may be implemented with light-emitting diodes (LEDs) that emit light with wavelengths in a visible region.

The driver unit 70 is a component that applies a predetermined bias voltage Vb between the first transparent conductive film 13 and the second transparent conductive film 23 to separate electrons and holes from electron-hole pairs.

The half mirror 65 is an optical element disposed on the light path in front of the light source 60 and changes the light path so that the read beam 61 emitted from the light source 60 is directed to the light detection panel 10 and 20.

The polarizing plate 30 is disposed on the light path between the photoconductor unit 10 and the half mirror 65, and the analyzer 40 is disposed on the light path in front of the liquid crystal unit 20, so that the transmittance of the read beam changes depending on the polarization transmittance characteristics of the liquid crystal layer 27.

The imaging lens 80 is disposed on the light path in front of the analyzer 40. Therefore, the imaging lens 80 focuses the read beam transmitted through the analyzer 40 so as to be imaged by the image pickup unit 85.

The image pickup unit 85 is a device that detects the read beam 61 delivered from the imaging lens 80 and produces an image from which a state of a subject can be diagnosed. The image pickup unit 85 is implemented with a CCD camera or a CMOS camera.

As illustrated in FIG. 1, the liquid crystal X-ray detector according to one embodiment of the present invention has a structure in which the photoconductor unit 10 and the liquid crystal unit 20 are in face contact with each other. When the photoconductor unit 10 is exposed to X-rays, electrons and holes are created in the photoconductive layer (i.e., selenium layer) 17. In this state, when a DC electric field is applied between the first transparent conductive film 13 and the second transparent conductive film 23, a polarization phenomenon occurs in which the electrons and the holes move to their opposite polarity side, i.e., to the first transparent conductive film and the second conductive film, respectively, for example, or vice versa.

Referring to FIG. 4, since a positive voltage is applied to the first transparent conductive film 13, the holes are distributed in a lower portion of the selenium layer 17 and the electrons are distributed in an upper portion of the selenium layer 17. That is, the holes gather in a region near the liquid crystal layer 27 and the electrons gather in a region near the first transparent conductive film 13.

This polarization phenomenon affects the liquid crystal layer 27, thereby changing the state of the liquid crystal. That is, when the charge distribution changes as shown in FIG. 4, the arrangement of liquid crystals in the liquid crystal layer 27 changes.

More specifically, the electrons and holes are separated in the photoconductive layer (i.e., selenium layer) 17 irradiated with X-rays, thereby blocking the internal electric field of the photoconductive layer 17. Therefore, the voltage applied to the liquid crystal layer 27 increases.

In the example of FIG. 4, a voltage applied to liquid crystal cells in a region A which is not irradiated with X-rays differs from a voltage applied to liquid crystal cells in a region B which is irradiated with X-rays. Therefore, the liquid crystal layer 27 locally varies in the polarization transmittance characteristic with respect to the read beam depending on whether it is irradiated with X-rays or not. Because of the local variation in the polarization transmittance characteristics throughout the liquid crystal layer 27, the power of the read beam that exits the analyzer after passing through the polarizing plate 30 varies. Therefore, an X-ray image for diagnosing the state of a subject can be obtained from the light exiting the analyzer 40.

Referring to FIG. 4, the read beam incident on the region A can pass through the analyzer 40 but the read beam incident on the region B cannot pass through the analyzer 40.

Accordingly, the optical path of the read beam that is emitted from the light source is changed by the half mirror 65 so that the read beam can sequentially pass through the polarizing plate 30, the photoconductor unit 10, the liquid crystal unit 20, and the analyzer 40 and can then be selectively incident on the imaging lens 80. The image pickup unit 85 detects the light delivered from the imaging lens 80 to obtain an X-ray image of a subject.

Although preferred embodiments of the present invention have been described and illustrated using specific terms, it is apparent that those terms are used only for clarification of the present invention but not for limiting the scope of the present invention. Accordingly, it is apparent that those embodiments and terms can be modified, changed, altered, and substitutes without departing from the technical spirit and scope of the present invention as defined in the appended claims. It should be noted that modifications and equivalents to the embodiments fall within the scope of the present invention.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method of manufacturing a liquid crystal X-ray detector, the method comprising:
preparing a photoconductor unit;
preparing a liquid crystal unit; and
bonding the photoconductor unit and the liquid crystal unit to each other,
wherein the preparing of the photoconductor unit comprises a first step of forming a selenium layer on a first substrate and a second step of forming a first alignment film on the selenium layer, and
the second step comprises a coating step of coating a surface of the selenium layer with parylene to form the first alignment film.

2. The method according to claim 1, wherein the second step further comprises a vaporization step of vaporizing parylene dimer and a decomposition step of decomposing the vaporized parylene dimer into parylene monomer by applying heat or plasma energy to the vaporized parylene dimer, and
the coating step is a step of depositing the parylene monomer on the selenium layer at a temperature lower than 45° C. in a vacuum atmosphere.

3. The method according to claim 1, wherein the preparing of the liquid crystal unit comprises forming a second alignment film on a second substrate and dispersing liquid crystals on the second alignment film, and
the bonding is to bond the photoconductor unit and the liquid crystal unit to each other such that the second alignment film faces the first alignment film.

4. The method according to claim 1, further comprising:
rubbing the parylene formed on the selenium layer through the coating step; and
forming a sealing member.

5. A liquid crystal X-ray detector comprising:
a photoconductor unit; and
a liquid crystal unit provided on the photoconductor unit,
wherein the photoconductor unit comprises a first substrate, a selenium layer formed on the first substrate, and a first alignment film formed on the selenium layer, and
the first alignment film is formed of parylene.

6. The liquid crystal X-ray detector according to claim 5, wherein the first alignment film is formed of parylene deposited at a temperature lower than 45° C. in a vacuum atmosphere.

7. The liquid crystal X-ray detector according to claim 5, wherein the liquid crystal unit comprises a second substrate, a second alignment film formed on the second substrate and opposed to the first alignment film, and a liquid crystal layer provided between the first alignment film and the second alignment film.

8. The liquid crystal X-ray detector according to claim 7, further comprising:
a first transparent conductive film formed on the first substrate;
an insulating film formed on the first transparent conductive film;
a second transparent film formed on the second substrate; and
a driver unit,
wherein the selenium layer is formed on the insulating film,
the second alignment film is formed on the second transparent conductive film, and
the driver unit applies a voltage between the first transparent conductive film and the second transparent conductive film.

9. The liquid crystal X-ray detector according to claim 5, wherein further comprising:
an X-ray output unit that emits an X-ray;
a light source that emits a read beam;
a polarizing plate disposed on a light path behind the photoconductor unit;
an analyzer disposed on a light path in front of the liquid crystal unit; and
an image pickup unit that forms an image from the read beam transmitted through the analyzer.

10. The method according to claim 2, further comprising:
rubbing the parylene formed on the selenium layer through the coating step; and
forming a sealing member.
